(19) United States
(12) Patent Application Publication
(10) Pub. No.: US 2025/0380393 A1
(43) Pub. Date: Dec. 11, 2025

(54) REEL WORK DEVICE

(71) Applicant: FUJI CORPORATION, Chiryu (JP)

(72) Inventor: Mizuho NOZAWA, Kota-cho (JP)

(73) Assignee: FUJI CORPORATION, Chiryu (JP)

(21) Appl. No.: 18/874,363

(22) PCT Filed: Jul. 28, 2022
(86) PCT No.: PCT/JP2022/029095

§ 371 Date: Dec. 12, 2024

(51) Int. Cl. H05K 13/02; H05K 13/04

(52) U.S. Cl. CPC H05K 13/021; H05K 13/0419

(57) ABSTRACT

A reel work device includes a feeder holding section configured to hold a feeder loaded with a reel, a removal device configured to remove the reel from the feeder held by the feeder holding section, and a discharge section configured to discharge the removed reel to an outside of the device.

### TECHNICAL FIELD

The present disclosure relates to a reel work device.

### BACKGROUND ART

A reel work device is applied to, for example, a setup operation for board production of a board product. The setup operation includes a reel loading operation to a feeder and a reel removing operation from the feeder. Patent Literature 1 discloses a configuration in which a reel is automatically loaded to a tape feeder.

### CITATION LIST

### Patent Literature

Patent Literature 1: International Publication No. 2021/106026

### BRIEF SUMMARY

### Technical Problem

A reel removed from a feeder in a reel work device is inserted into, for example, a retrieval box installed in the reel work device and retrieved by a worker. In order to increase a time that the reel removing operation can be continued by the reel work device, it is necessary to increase the size of the retrieval box or increase the frequency of retrieval by the worker.

An object of the present description is to provide a reel work device capable of increasing the number of removable reels that can be discharged without increasing the size of a retrieval box.

### Solution to Problem

The present description discloses a reel work device including a feeder holding section configured to hold a feeder loaded with a reel, a removal device configured to remove the reel from the feeder held by the feeder holding section, and a discharge section configured to discharge the removed reel to an outside of the reel work device.

### Advantageous Effects

According to such a configuration, the reel removed from the feeder can be discharged to the outside of the reel work device, and the number of the removed reels that can be discharged can be increased without increasing the size of the retrieval box in the reel work device. As a result, it is possible to increase a time that reel removal processing can be continued by the reel work device.

### BRIEF DESCRIPTION OF DRAWINGS

FIG. 1 is a plan view schematically illustrating a setup device.

FIG. 2 is a perspective view illustrating a discharge section in a reel loading device.

FIG. 3 is a functional block diagram of the reel loading device.

FIG. 4 is a flowchart illustrating a reel discharge processing.

FIG. 5 is a perspective view illustrating a reel loading device in a modification of the embodiment.

### DESCRIPTION OF EMBODIMENTS

A setup device to which a reel work device is applied will be described with reference to the drawings. The setup device is a device that executes or supports various setup operations as preparation for production of a board product. In the present embodiment, a setup device that executes a reel loading operation of loading a reel to a tape feeder as a setup operation is exemplified.

### 1. Setup Device 10

Setup device 10 is installed, for example, in an off-line setup area between a warehouse for storing components (not illustrated) and a production line in a production facility of a board product. In the off-line setup area, the operation of loading reel 92 to feeder 91 can be automatically performed by setup device 10, or be manually performed by a worker. When multiple types of setup devices 10 corresponding to the type of feeder 91 are installed, setup devices 10 may be switched and used. Further, between the off-line setup area and the warehouse, and between the off-line setup area and the production line, an automated guided vehicle and the worker can convey feeder 91 and the components.

### 1-1. Reel Loading Device 11

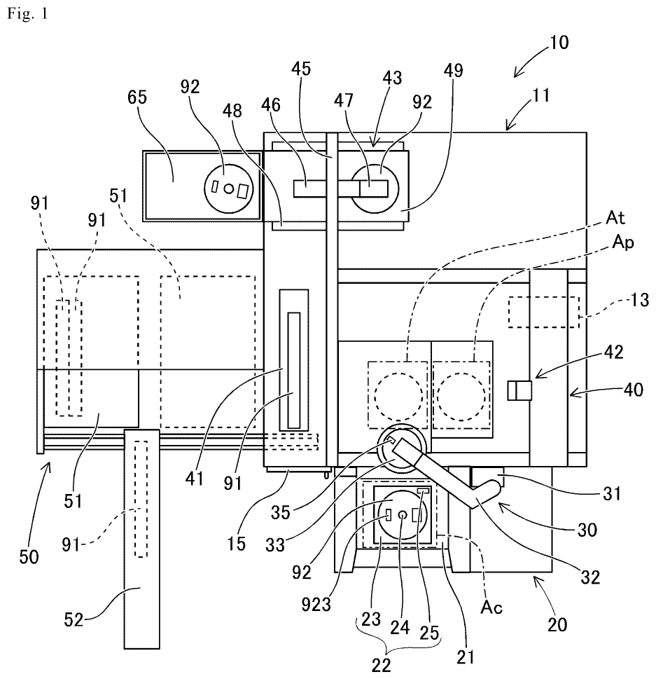

As illustrated in FIG. 1, setup device 10 includes reel loading device 11. Reel loading device 11 is a reel work device that executes a reel loading operation to feeder 91. Reel loading device 11 includes reel supply device 20 and reel attachment/detachment device 40.

### 1-1-1. Reel Supply Device 20

Reel supply device 20 temporarily holds multiple reels 92 carried in from the outside, and supplies reel 92 necessary for reel attachment/detachment device 40. Reel supply device 20 detachably supports reel holding section 22 on an upper surface of pedestal 21. Reel holding section 22 stacks and holds multiple reels 92 in a horizontal posture (a posture in which a rotation axis of reel 92 is oriented in a vertical direction). Reel 92 held by reel holding section 22 may include not only an unused reel but also a reel that has been partially used.

Reel holding section 22 holds multiple reels 92 by having round rod-shaped holding shaft 24 provided upward from the center of circular plate-shaped holding plate 23 and passing through a center hole of reel 92. Holding section code 25 indicating identification information (ID) for specifying reel holding section 22 is attached to an upper surface of holding plate 23. Holding section code 25 is used to manage multiple reels 92 held by reel holding section 22.

Reel supply device 20 includes reel transfer device 30 serving as a moving device that moves reel 92 to reel attachment/detachment device 40. Reel transfer device 30 is provided above pedestal 21. Reel transfer device 30 includes arm 32 that is provided to be liftable and lowerable with respect to column 31 extending in the vertical direction and to be rotatable around a vertical axis.

Arm 32 is provided with collection section 33 capable of extending and contracting in a horizontal direction. Collection section 33 detachably collects reel 92. Various aspects may be adopted as a collection method of collection section 33. For example, collection section 33 may grip the peripheral edge and the center hole of reel 92, or may pick up and collect the upper surface (flange surface in the horizontal posture) of reel 92 by a negative pressure air.

Collection section 33 is provided with reader 35. Reader 35 reads holding section code 25 of reel holding section 22. Reader 35 can read reel code 923 attached to uppermost reel 92 held by reel holding section 22 or to reel 92 collected by collection section 33. Reel code 923 indicates identification information (ID) that specifies reel 92.

Reel supply device 20 configured as described above is carried in carry-in area Ac and is configured to supply multiple reels 92 held by reel holding section 22. When reel transfer device 30 drives arm 32 and collection section 33, reel supply device 20 places one reel 92 collected from reel holding section 22 in placement area Ap or temporary placement area At on reel attachment/detachment device 40 side in a state in which reel 92 is in the horizontal posture.

### 1-1-2. Reel Attachment/Detachment Device 40

Reel attachment/detachment device 40 performs an operation of setting reel 92 necessary for production to feeder 91, and an operation of removing reel 92 that became no longer necessary for production from feeder 91. Reel attachment/detachment device 40 includes feeder holding section 41 that holds feeder 91 carried in from feeder supply device 50 to be described later.

When feeder 91 is held by feeder holding section 41, feeder 91 is electrically connected to setup device 10 via a connector (not illustrated). As a result, feeder 91 is in a state of being able to communicate with control device 13 of setup device 10, which will be described later, and is in a state in which it is possible to operate a drive device that feeds and moves carrier tape paid out from loaded reel 92.

Reel attachment/detachment device 40 includes setting device 42 that sets reel 92 to feeder 91 held by feeder holding section 41. Setting device 42 collects reel 92 in the horizontal posture in placement area Ap and changes the posture to a vertical posture (posture in which the rotation axis of reel 92 is oriented in the horizontal direction). Setting device 42 moves reel 92 in the vertical posture to feeder 91, and causes feeder 91 to hold reel 92.

In placement area Ap described above, reel 92 to be attached to feeder 91 held by feeder holding section 41 is placed in the horizontal posture. Further, in temporary placement area At, when it is necessary to change the order in which setting device 42 sets multiple reels 92 to feeder 91, reel 92 on which the set order is postponed is temporarily placed in the horizontal posture.

Setting device 42 has such a tape loading function that feeder 91 is set in a loading state in which a carrier tape paid out from reel 92 can be fed and moved by the drive device. Specifically, setting device 42 includes, for example, an articulated robot and an image processing device. Setting device 42 recognizes a leading end portion of carrier tape by the image processing device. Setting device 42 grips the leading end portion of carrier tape with the finger of the articulated robot, and engages a sprocket hole of carrier tape with a sprocket constituting the drive device of feeder 91.

Accordingly, reel 92 used for production is set to feeder 91, and feeder 91 is set in a loading state in which the carrier tape can be fed and moved. Feeder 91 on which reel 92 is set is removed from feeder holding section 41 and carried out to feeder supply device 50.

Reel attachment/detachment device 40 includes removal device 43 for removing reel 92 from feeder 91 held by feeder holding section 41. Removal device 43 moves movable base 46 along guide rail 45, and removes reel 92 set on feeder 91 by collection section 47 provided on movable base 46. Removal device 43 changes removed reel 92 from the vertical posture to the horizontal posture, and inserts reel 92 into discharge section 60 that discharges reel 92 to the outside of the device. Details of discharge section 60 will be described later.

### 1-2. Feeder Supply Device 50

As illustrated in FIG. 1, setup device 10 includes feeder supply device 50. Feeder supply device 50 is installed side by side with reel loading device 11, temporarily holds multiple feeders carried in from the outside, and supplies necessary feeders 91 to reel loading device 11. Feeder supply device 50 includes feeder accommodation section 51 that is detachably provided and feeder conveyance section 52.

Feeder accommodation section 51 is accommodated alongside other feeder accommodation sections 51 in an accommodation space of a housing. Feeder accommodation section 51 is formed in a box shape having an opening portion in the horizontal direction. Feeder accommodation section 51 supports feeder 91 in multiple slots formed in the bottom surface. When feeder 91 is held in feeder accommodation section 51, feeder 91 is communicably connected to setup device 10 via a connector (not illustrated).

Feeder conveyance section 52 is configured to be movable between feeder accommodation section 51 and feeder holding section 41. Feeder conveyance section 52 takes out any feeder 91 from feeder accommodation section 51 and carries feeder 91 in feeder holding section 41. When unnecessary reel 92 is removed from feeder 91 and reel 92 necessary for production to be executed is loaded to feeder 91 by reel loading device 11, feeder conveyance section 52 carries out feeder 91 from feeder holding section 41 and accommodates feeder 91 in a predetermined slot of feeder accommodation section 51.

### 1-3. Control Device 13

As illustrated in FIG. 1, setup device 10 includes control device 13. Control device 13 controls operations of reel loading device 11 and feeder supply device 50, and executes various operations to feeder 91. The above-described operation includes, in addition to the reel loading operation in the setup operation, the operation of simply removing reel 92 in order to store feeder 91 in a state where reel 92 is not loaded in a warehouse or the like.

Control device 13 obtains multiple reels 92 held by reel holding section 22 carried into carry-in area Ac based on the reading result of holding section code 25 by reader 35 of reel transfer device 30. Further, control device 13 obtains uppermost reel 92 held by reel holding section 22 or reel 92 collected by collection section 33 of reel transfer device 30 based on the reading result of reel code 923 by reader 35.

Control device 13 obtains feeder 91 held by feeder holding section 41 and feeder 91 accommodated in feeder accommodation section 51 by communication. Based on the instruction of the setup operation, control device 13 loads corresponding reel 92 to predetermined feeder 91, or loads reel 92 to feeder 91 to be loaded.

Further, when reel 92 is loaded on feeder 91, control device 13 generates association information. When reel 92 is removed from feeder 91, control device 13 deletes the association information. The generation and deletion of the association information are shared by a management device that is the higher-level of setup device 10 as necessary. Control device 13 discharges reel 92 using discharge section 60 in the reel removal processing by removal device 43.

### 1-4. Safety Device 70

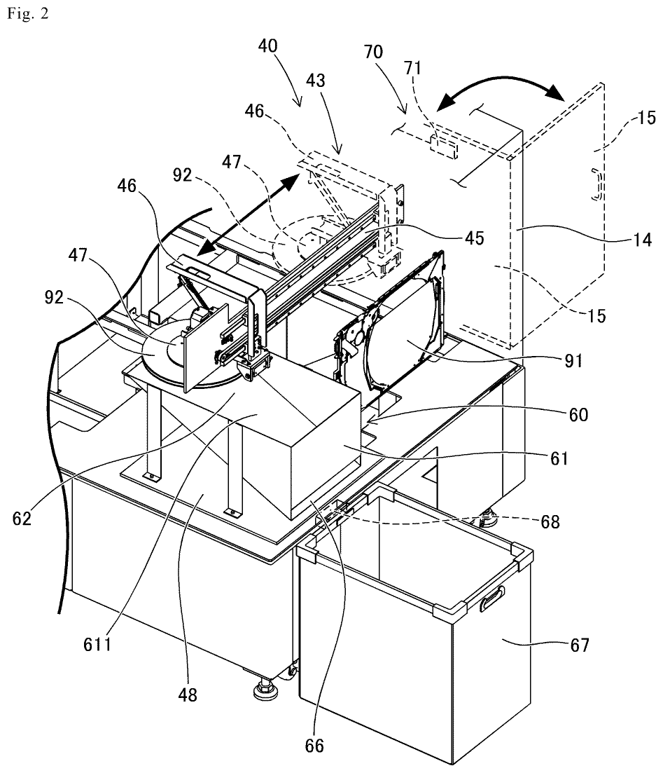

As illustrated in FIG. 2, reel loading device 11 of setup device 10 includes safety device 70. Safety device 70 disables some of the functions of reel loading device 11 in order to ensure the safety of the worker when the worker can access the inside of the device. In the present embodiment, safety device 70 is incorporated in control device 13, and restricts the operation of removal device 43 when door 15 provided on cover 14 that separates the inside and the outside of the device is in the open state.

Specifically, safety device 70 includes door sensor 71 that detects the open state of door 15. Safety device 70 transmits a restriction signal to control device 13 during a period in which the open state of door 15 is detected. Removal device 43 of reel attachment/detachment device 40 performs control so as not to perform operations such as movement and posture change of reel 92 during a period in which the restriction signal transmitted from safety device 70 is input.

Safety device 70 allows the operation of removal device 43 when door 15 is in the closed state. Specifically, when door 15 is closed, safety device 70 stops transmitting the restriction signal to control device 13. Accordingly, removal device 43 executes operations such as movement and posture change of reel 92 according to the command.

### 2. Discharge Section 60

### 2-1. Overview of Discharge Section 60

In reel loading device 11 as the reel work device configured as described above, operation of removing reel 92 from feeder 91 is executed. At this time, for example, when removed reel 92 is continuously inserted into the retrieval box installed in the device, reels 92 are stacked up to the number of removed reels 92 that can be accommodated in the retrieval box, and the reel removing operation cannot be continued.

In order to increase the time that the reel removing operation can be continued, it is necessary to increase the size of the retrieval box or increase the frequency of retrieval from the retrieval box by the worker. However, since there is a limited space in the device, it is not easy to increase the size of the retrieval box, and when the frequency of the retrieval is increased, the number of operations by the worker increases. Therefore, in the present embodiment, a configuration is adopted in which the number of removable reels that can be discharged can be increased without increasing the size of the retrieval box.

Specifically, in the present embodiment, reel loading device 11 includes discharge section 60 that discharges the removed reel to the outside of the device. Accordingly, the number of reels 92 discharged by reel loading device 11 in the reel removing operation can be increased. As a result, it is possible to increase the time that the reel removing operation can be continued by reel loading device 11. As illustrated in FIG. 2, discharge section 60 is configured such that reel 92 in a horizontal posture held by removal device 43 can be inserted.

### 2-2. Configuration of Discharge Section 60

As illustrated in FIG. 2, discharge section 60 includes chute 61 as a main body. Chute 61 is fixed to installation base 48 in the device. Chute 61 is formed with inlet 62 into which removed reel 92 is inserted. Inlet 62 is opened such that reel 92 in the horizontal posture can pass through inlet 62. Chute 61 guides reel 92 inserted into inlet 62 to the outside of the device. Chute 61 also has slope 611 that guides inserted reel 92 to the outside of the device while reel 92 slides so that inserted reel 92 is discharged in a predetermined posture.

Slope 611 extends from below inlet 62 to cover 14. In a lower portion of chute 61, discharge port 66 for discharging reel 92 inclined by an amount corresponding to the inclination of slope 611 from the horizontal posture is formed. Discharge port 66 communicates with a slit formed in cover 14 so that reel 92 can pass therethrough. Storage box 67 that accommodates reel 92 discharged from discharge section 60 to the outside of the device is detachably installed below discharge port 66 outside setup device 10. As storage box 67, a storage box capable of accommodating a larger number than a retrieval box dedicated to the inside of the device is used, and any shape can be selected.

Replacement of storage box 67 by a worker or the like and retrieval of reel 92 from storage box 67 correspond to the work outside the device. Therefore, the retrieval work of reel 92 is not a target of a measure of temporarily stopping, for example, the reel work (the loading operation or the removing operation of reel 92) in the device accompanying the retrieval of reel 92 from the viewpoint of ensuring safety or the like.

In the present embodiment, box sensor 68 is embedded in a portion of the wall surface of cover 14 that comes into contact with installed storage box 67. Box sensor 68 detects storage box 67 installed at a predetermined position and transmits a signal to control device 13. When storage box 67 is removed by a worker or the like, box sensor 68 is in a state of not detecting storage box 67, and stops transmitting the signal to control device 13.

### 3. Discharge Control Section 80

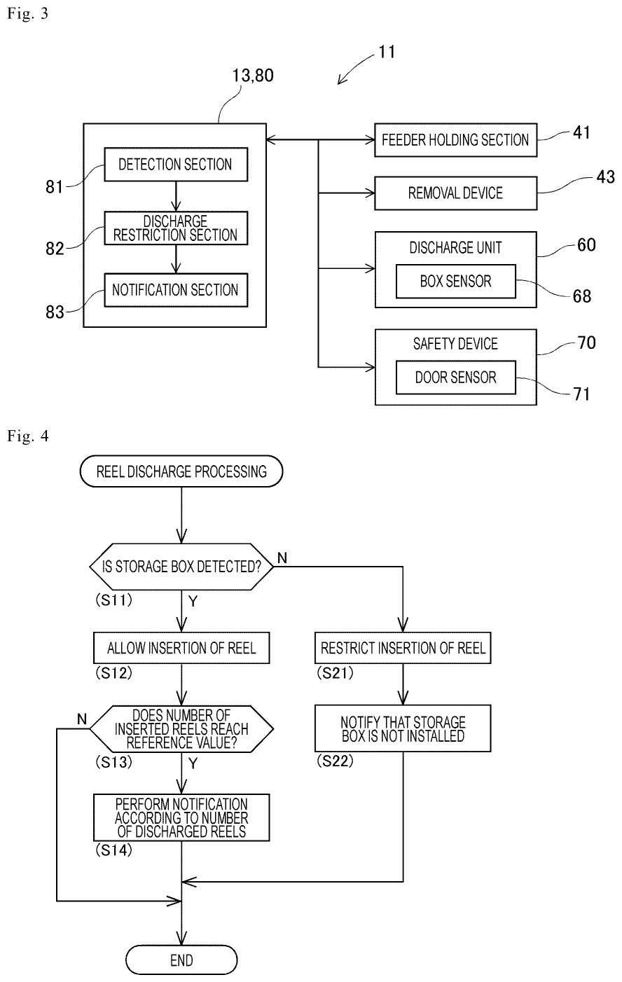

In the present embodiment, as illustrated in FIG. 3, control device 13 includes discharge control section 80 that controls the discharge operation of reel 92 as some of the reel removing operation. Discharge control section 80 controls the operation of removal device 43 using various functions of control device 13. In addition, as illustrated in FIG. 4, discharge control section 80 executes a processing of discharging reel 92 after removal device 43 removes reel 92 from feeder 91.

### 3-1. Detection Section 81

As illustrated in FIG. 3, discharge control section 80 includes detection section 81. Detection section 81 detects installation of storage box 67 that accommodates reel 92 discharged from discharge section 60 to the outside of the device. Specifically, when storage box 67 is installed at a predetermined position outside the device, box sensor 68 embedded in cover 14 detects storage box 67, and a signal is transmitted. Detection section 81 recognizes that storage box 67 is installed while the signal is input. For example, when storage box 67 is taken out by exchange operation or the like and the transmitting of the signal by box sensor 68 is stopped, detection section 81 recognizes that storage box 67 is not installed.

### 3-2. Discharge Restriction Section 82

As illustrated in FIG. 3, discharge control section 80 includes discharge restriction section 82. When storage box 67 is not detected by detection section 81 (S11: No in FIG. 4), discharge restriction section 82 restricts the discharge of reel 92 to the outside of the device. Specifically, discharge restriction section 82 restricts removal device 43 from inserting reel 92 held by removal device 43 into discharge section 60 (S21).

When storage box 67 is detected by detection section 81 (S11: Yes), discharge restriction section 82 allows removal device 43 to insert reel 92 into discharge section 60 (S12). In this manner, discharge restriction section 82 determines whether reel 92 can be inserted into discharge section 60 according to the presence or absence of storage box 67 outside the device. Accordingly, for example, it is possible to prevent reel 92 from being discharged even though storage box 67 is not installed.

### 3-3. Notification Section 83

As illustrated in FIG. 3, discharge control section 80 includes notification section 83. Notification section 83 executes various notification processing to the worker. The notification processing is performed by lighting a display lamp, performing notification to a terminal device carried by the worker, or the like. For example, when the discharge of reel 92 is restricted by discharge restriction section 82 (S21), notification section 83 notifies the worker that storage box 67 is not installed (S22).

In addition, discharge control section 80 accumulates the number of reels 92 whose discharge is allowed by discharge restriction section 82 (S12) and that are actually inserted into discharge section 60 by removal device 43. When the number of inserted reels 92 reaches a reference value set in advance (S13: Yes), notification section 83 performs notification according to the number of reels 92 discharged from discharge section 60 (S14). The “reference value” is set according to, for example, the number of reels that can be stored in storage box 67. Notification section 83 performs notification for prompting replacement of storage box 67 or retrieval of reel 92 before storage box 67 is filled by insertion of reels 92 a predetermined number of times.

### 4. Effects by Configuration of Embodiment

According to the above configuration, reel 92 removed from feeder 91 is discharged to the outside of the device, and the number of removed reels 92 that can be discharged can be increased without increasing the size of the retrieval box in the device. As a result, it is possible to increase the time that the reel removal processing can be continued by reel loading device 11 as the reel work device.

### 5. Modification of Embodiment

### 5-1. Discharge Section

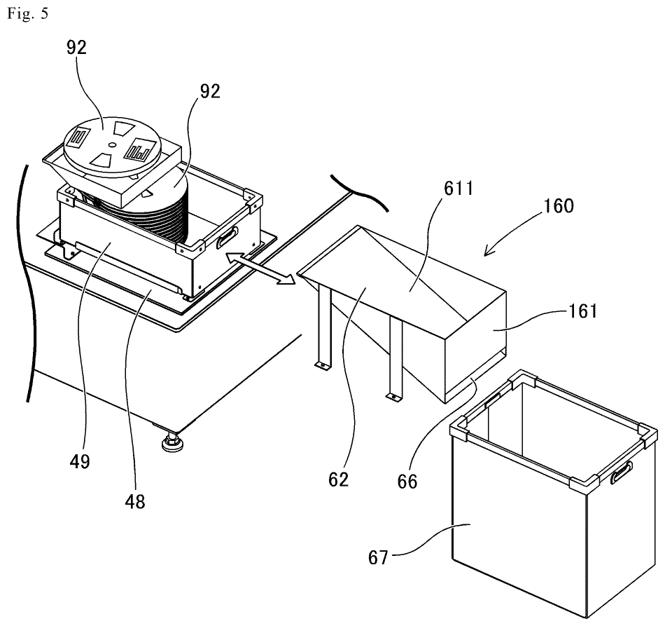

In the embodiment, discharge section 60 is fixed to installation base 48 of setup device 10 inside the device, and discharge port 66 of chute 61 communicates with the slit of cover 14. Meanwhile, as illustrated in FIG. 5, retrieval box 49 similar to the conventional retrieval box may be detachably installed on installation base 48. Thus, the setup operation can be performed without installing storage box 67 outside setup device 10.

In addition, in consideration of the contents of the setup operation and the time that the reel removal processing can be continued, discharge section 160 may be fixed to installation base 48 and storage box 67 may be installed instead of retrieval box 49 dedicated to the inside of the device. This makes it possible to be adopted to various operations such as the installation status of setup device 10 and the type of setup operation.

Discharge sections 60 and 160 each include inlet 62 and chute 61. Meanwhile, the discharge section may adopt various forms as long as reel 92 can be discharged to the outside of the device. For example, the discharge section may be configured to discharge reel 92 by a conveyor or the like. Alternatively, the discharge section may be configured to receive reel 92 in the vertical posture from removal device 43, rotate reel 92 by its own weight, and guide reel 92 to the outside of the device. The reel work device may include multiple discharge sections. For example, the reel work device may sort and discharge the reels to multiple discharge sections having different discharge destinations depending on purposes. The above object includes, for example, sorting between a reel in which a component remains and a reel in which the component is completely used, and sorting according to the material of the reel.

### 5-2. Reel Work Device

In the embodiment, for example, the reel work device is reel loading device 11 that loads reel 92 to feeder 91. Meanwhile, the reel work device includes removal device 43 that removes reel 92 from feeder 91 held by feeder holding section 41, and discharge sections 60 and 160 can be applied as long as the reel work device has at least a reel removal function. The same effect can be obtained from such a configuration.

Reel loading device 11 as the reel work device includes detection section 81, discharge restriction section 82, and notification section 83. Meanwhile, reel loading device 11 may have a configuration in which some thereof are omitted, for example, a configuration in which storage box 67 or retrieval box 49 is normally installed in reel loading device 11 and detection section 81 or discharge restriction section 82 is not provided. Some of the notification processing (S14, S22) by notification section 83 may be omitted. However, from the viewpoint of maintaining the efficiency of the setup operation, the aspect exemplified in the embodiment is preferable.

### REFERENCE SIGNS LIST

10: setup device, 11: reel loading device (reel work device), 13: control device, 14: cover, 15: door, 20: reel supply device, 30: reel transfer device, 40: reel attachment/detachment device, 41: feeder holding section, 42: setting device, 43: removal device, 45: guide rail, 46: movable base, 47: collection section, 48: installation base, 49: storage box, 50: feeder supply device, 60, 160: discharge section, 61, 161: chute, 611: slope, 62: inlet, 66: discharge port, 67: storage box, 68: box sensor, 70: safety device, 71: door sensor, 80: discharge control section, 81: detection section, 82: discharge restriction section, 83: notification section, 91: feeder, 92: reel, Ap: placement area, At: temporary placement area, Ac: carry-in area

1. A reel work device comprising:
a feeder holding section configured to hold a feeder loaded with a reel;
a removal device configured to remove the reel from the feeder held by the feeder holding section; and
a discharge section configured to discharge the removed reel to an outside of the reel work device.

2. The reel work device according to claim 1,
wherein the discharge section includes
an inlet into which the removed reel is inserted, and
a chute configured to guide the reel inserted into the inlet to the outside of the reel work device.

3. The reel work device according to claim 2, wherein the chute has a slope that guides the inserted reel to the outside of the reel work device while the reel slides so that the inserted reel is discharged in a predetermined posture.

4. The reel work device according to claim 1, further comprising:
a detection section configured to detect installation of a storage box that accommodates the reel discharged from the discharge section to the outside of the reel work device.

5. The reel work device according to claim 4, further comprising:
a discharge restriction section configured to restrict discharge of the reel to the outside of the reel work device when the storage box is not detected by the detection section.

6. The reel work device according to claim 1, further comprising:
a notification section configured to notify a worker of a notification according to presence or absence of a storage box that accommodates the reel discharged from the discharge section to the outside of the reel work device, or the number of reels discharged from the discharge section.

7. The reel work device according to claim 1, further comprising:
a safety device configured to restrict an operation of the removal device when a door provided on a cover that separates an inside and the outside of the reel work device is in an open state and allow the operation of the removal device when the door is in a closed state.
